(19) United States
(12) Patent Application Publication
(10) Pub. No.: US 2024/0164059 A1
(43) Pub. Date: May 16, 2024

(54) VAPOR CHAMBER STRUCTURE

(71) Applicant: ASIA VITAL COMPONENTS (CHINA) CO., LTD., Shenzhen (CN)

(72) Inventors: Han-Min Liu, Shenzhen (CN); Wen-Qi Liu, Shenzhen (CN); Xing-Hui Li, Shenzhen (CN); Xiao-Xiang Zhou, Shenzhen (CN)

(21) Appl. No.: 18/123,345

(22) Filed: Mar. 20, 2023

(30) Foreign Application Priority Data
Nov. 15, 2022 (TW) 111143580

(51) Int. Cl. H05K 7/20; F28D 15/02

(52) U.S. Cl. CPC H05K 7/20309; F28D 15/02; F28D 2015/0216

(57) ABSTRACT

A vapor chamber structure includes an aluminum upper plate, an aluminum lower plate, a working fluid and multiple micron-sized recesses. The aluminum upper plate has a first side and a second side. The aluminum lower plate has a third side and a fourth side. The aluminum upper and lower plates are correspondingly mated with each other to define an airtight chamber. The working fluid is filled in the airtight chamber. The micron-sized recesses are directly formed on the third side. The micron-sized recesses are upward raised and/or downward recessed from the third side in the form of multiple small puddles so as to enhance the boiling efficiency of the working fluid in the airtight chamber and promote liquid-vapor circulation performance of the vapor chamber. In addition, when used in a low-temperature environment, the vapor chamber structure prevents the working fluid in the airtight chamber from freezing.

This application claims the priority benefit of Taiwan patent application number 111143580 filed on Nov. 15, 2022.

### BACKGROUND OF THE INVENTION

### 1. Field of the Invention

The present invention relates generally to a vapor chamber structure, and more particularly to a vapor chamber, which has a thinned structure and can prevent the working fluid from freezing in a low-temperature environment.

### 2. DESCRIPTION OF THE RELATED ART

A vapor chamber is one of the often seen heat conduction components. According to two-phase fluid principle, the vapor chamber provides fast heat conduction effect for a heat source. A working fluid (such as water, coolant, methanol, propylene alcohol or liquid ammonia) is filled in the vapor chamber. The outer case of the vapor chamber is generally mainly made of copper or stainless steel material. A latent heat system of change between two phases of the working fluid takes place in the vapor chamber so as to transfer the heat so that the heat conduction capability of the vapor chamber reaches 10000c/w. The superconductive capability of the vapor chamber is well applied to electronic, aeronautical, military and petrochemical industries.

In recent years, the heat flux density of chip packaging has become higher and higher. When chip power consumption reaches 1000W, the heat flux density reaches 250 W/cm₂. In addition, due to hotspot problem of the chip, the requirement for thermal resistance of vapor chamber (VC) has become stricter and stricter. It has become a primary focus in design of two-phase fluid product how to reduce the thermal resistance inside the vapor chamber.

The higher the power of the heat source is, the larger the required volume or area of the vapor chamber included in a thermal module is so that the heat can be quickly dissipated. However, in the case that the thermal module is made of copper and stainless steel material, the total weight of the thermal module is quite heavy. When the heavy thermal module is pressed against the PCB or the chip, the PCB or the chip is apt to be fractured and damaged. In addition, the use environment problem must be more seriously taken into consideration. When used in a low-temperature environment, the working fluid in the vapor chamber is required to be able to start to work in the low-temperature environment without freezing. Moreover, it should be further noted that the change of the environment temperature will lead to freezing and expansion of the working fluid in the vapor chamber. The expansion of the working fluid will lead to fracture of the case body.

It is therefore tried by the applicant to provide a vapor chamber structure to solve the above problems existing in the conventional vapor chamber. The vapor chamber structure of the present invention can speed the boiling of the working fluid in the airtight chamber and lower the evaporation thermal resistance. Moreover, the vapor chamber structure of the present invention enables the bubbles produced after the working fluid is evaporated to easily escape from the capillary structure so as to achieve better heat exchange effect.

### SUMMARY OF THE INVENTION

It is therefore a primary object of the present invention to provide a lightweight vapor chamber structure having better structural strength. When the vapor chamber structure is applied to a low-temperature environment, the working fluid in the airtight chamber is prevented from freezing. In addition, the boiling of the working fluid in the airtight chamber is speeded so as to lower the evaporation thermal resistance.

To achieve the above and other objects, the vapor chamber structure of the present invention includes an aluminum upper plate, an aluminum lower plate, a working fluid and multiple micron-sized recesses.

The aluminum upper plate has a first side and a second side. The aluminum lower plate has a third side and a fourth side. The aluminum upper plate and the aluminum lower plates are correspondingly mated with each other to define an airtight chamber. The working fluid is filled in the airtight chamber. The micron-sized recesses are directly formed on a surface of the third side. The micron-sized recesses are upward raised and/or downward recessed from the surface of the third side in the form of multiple small puddles so as to enhance the boiling efficiency of the working fluid in the airtight chamber and promote liquid-vapor circulation performance of the entire vapor chamber. In addition, when used in a low-temperature environment, the vapor chamber structure prevents the working fluid in the airtight chamber from freezing.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein:

FIG. 1 is a perspective exploded view of a first embodiment of the vapor chamber structure of the present invention;

FIG. 2 is a sectional assembled view of the first embodiment of the vapor chamber structure of the present invention; and

FIG. 3 is a perspective exploded view of a second embodiment of the vapor chamber structure of the present invention.

### DETAILED DESCRIPTION OF THE PREFERRED EMBODIMENTS

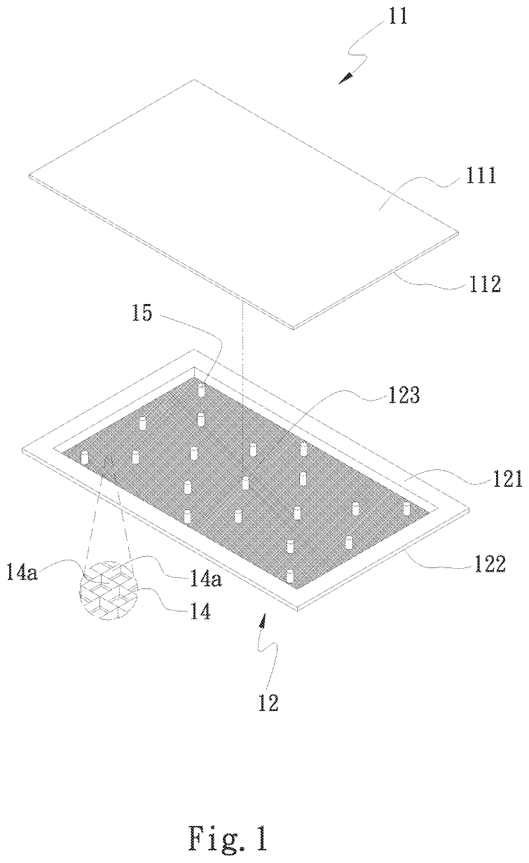

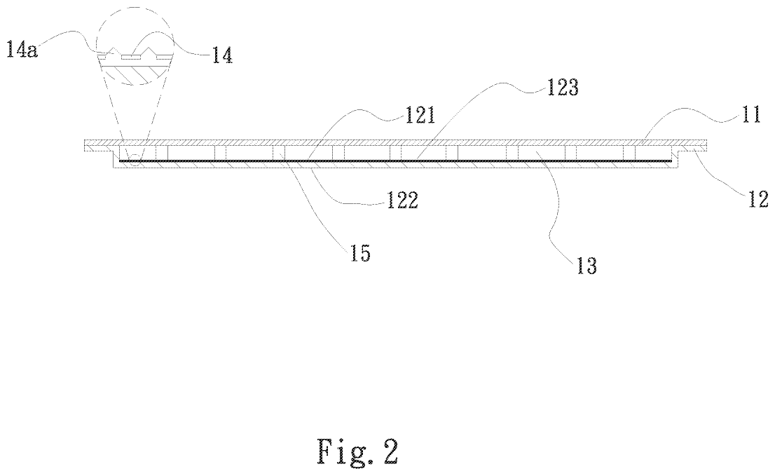

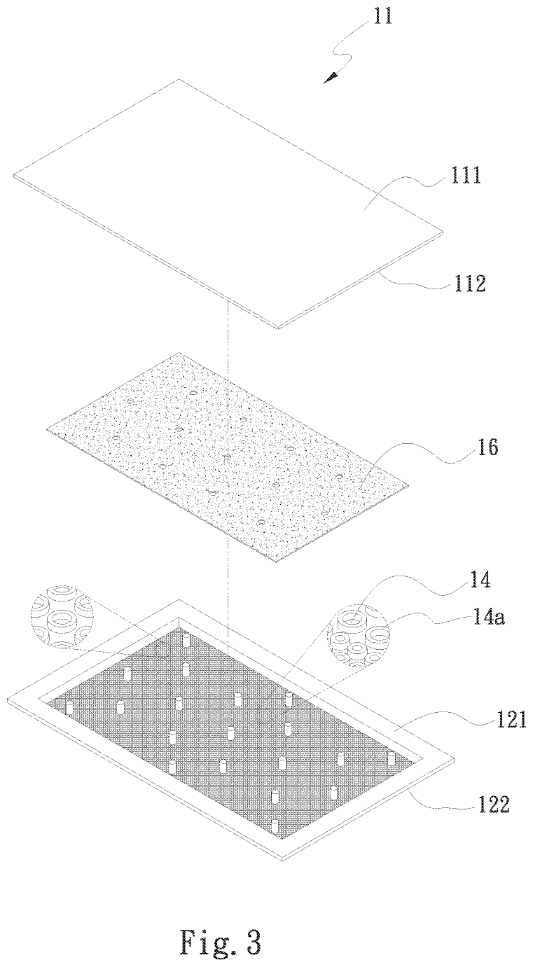

Please refer to FIGS. 1, 2 and 3. FIG. 1 is a perspective exploded view of a first embodiment of the vapor chamber structure of the present invention. FIG. 2 is a sectional assembled view of the first embodiment of the vapor chamber structure of the present invention. FIG. 3 is a perspective exploded view of a second embodiment of the vapor chamber structure of the present invention. As shown in the drawings, the vapor chamber structure of the present invention includes an aluminum upper plate 11, an aluminum lower plate 12, a working fluid and multiple micron-sized recesses 14.

The aluminum upper plate 11 has a first side 111 and a second side 112 respectively positioned on an upper side and a lower side of the aluminum upper plate 11.

The aluminum lower plate 12 has a third side 121 and a fourth side 122 respectively positioned on an upper side and a lower side of the aluminum lower plate 12. The third side 121 of the aluminum lower plate 12 has an evaporation section 123. A section of the fourth side 122 corresponding to the evaporation section 123 is in contact with at least one heat source (not shown) for conducting the heat thereof. The aluminum upper plate 11 and the aluminum lower plate 12 are correspondingly mated with each other, that is, the second side 112 of the aluminum upper plate 11 is correspondingly mated with the third side 121 of the aluminum lower plate 12 to define an airtight chamber 13. The working fluid (not shown) is filled in the airtight chamber 13.

The width of the micron-sized recesses 14 ranges from 200 μm to 300 μm and the depth of the micron-sized recesses 14 ranges from 30 μm to 50 μm. The micron-sized recesses 14 are directly formed on the evaporation section 123 of the surface of the third side 121 (by means of engraving or incision), whereby the micron-sized recesses 14 have the form of more than one small puddles (pits, pools, holes or ponds) upward raised and/or downward recessed from the evaporation section 123. The micron-sized recesses 14 have multiple small spaces for containing liquid. Accordingly, the boiling of the working fluid in the airtight chamber 13 is speeded so as to greatly enhance the liquid-vapor circulation efficiency of the entire vapor chamber.

The micron-sized recesses 14 have a geometrical configuration such as rectangular shape, rhombic shape, square shape, circular shape, trapezoidal shape or triangular shape. The micron-sized recesses 14 are arranged at equal intervals or unequal intervals. Alternatively, the micron-sized recesses 14 are arranged in adjacency to each other or nonadjacent to each other or disconnected from each other or immediately adjacent to each other or connected with each other.

The vapor chamber structure of the present invention further includes multiple support bodies 15 in the form of column structures. The support bodies 15 can be independent bodies, (two ends of which are respectively connected with the second side and the third side). Alternatively, the support bodies 15 directly upward protrude from the third side and the protruding ends of the support bodies 15 are connected with the second side 112 of the aluminum upper plate 11. The support bodies 15 and the micron-sized recesses 14 can be selectively connected with each other or staggered from each other.

Please refer to FIG. 1. The micron-sized recesses 14 are positioned on the third side 121 and multiple ribs 14a are raised from the third side 121. The ribs 14a extend in a transverse direction and a longitudinal direction of the third side 121 to intersect each other and define the micron-sized recesses 14. Alternatively, the ribs 14a are directly raised from the third side 121 in an annular form to define multiple small closed sections as the micron-sized recesses 14, (such as small circles or small rectangular frames or small closed sections with any other geometrical configuration as shown in FIG. 3). Alternatively, the third side 121 is directly formed with multiple downward recessed pits as the micron-sized recesses 14. The ribs 14a or the pits are directly formed on the surface of the third side 121 by means of removing parts of the material of the third side 121 or pressing the surface of the third side 121. The micron-sized recesses 14 can be formed on the third side 121 by means of traditional processing or nontraditional processing. The traditional processing is selected from the group consisting of lathe, miller, planer, grinding machine and stamping press. The nontraditional processing is selected from the group consisting of laser processing, discharging processing, etching processing and 3D printing.

The micron-sized recesses 14 are more densely disposed and arranged on the evaporation section 123 of the third side 121, which mainly and directly corresponds to the heat source (not shown) so as to enhance the pool boiling efficiency. The micron-sized recesses 14 can be disposed and arranged on the remaining part of the third side 121 at equal intervals or unequal intervals.

A capillary structure layer (not shown) is further disposed on the micron-sized recesses 14. The capillary structure layer is a sintered powder body or woven meshes or a fiber body. The capillary structure layer is disposed on and tightly bonded with the micron-sized recesses 14 by means of welding or diffusion bonding or sintering.

The upper and lower plates of the vapor chamber of the present invention are selectively mainly made of aluminum material. This solves the problem of the conventional vapor chamber, which results from the over-weighted copper material or stainless steel material. In addition, thank to the properties of the aluminum material, when used in a low-temperature environment, the working fluid contained in the vapor chamber is prevented from freezing.

When the aluminum lower plate is heated, the liquid working fluid is converted into vapor to spread upward. The multiple puddles (or pits) formed from the micron-sized recesses 14 divide a large region of the aluminum lower plate in contact with the working fluid into numerous tiny regions as numerous tiny nucleation points. After the working fluid in the aluminum lower plate is heated, the numerous tiny nucleation points can speed the boiling (nuclear boiling phenomenon) of the working fluid. Accordingly, the bubbles produced after the working fluid is evaporated can quickly escape and evaporate to form pool boiling and flow boiling phenomena. This enhances the severe change between two phases of the working fluid in the airtight chamber. The vapor chamber structure of the prevent invention is different from the conventional vapor chamber in that the boiling phase changes of pool boiling, film boiling and flow boiling take place at the same time in the vapor chamber structure of the prevent invention so that the heat transfer caused by the change between two phases of the working fluid is speeded. Therefore, the vapor chamber can immediately or instantaneously provide heat dissipation effect. The conventional vapor chamber can only provide traditional evaporation and film boiling. In comparison with the conventional vapor chamber, the vapor chamber structure of the prevent invention obviously has better heat transfer efficiency. Therefore, in comparison with the conventional vapor chamber, the vapor chamber structure of the prevent invention can additionally provide severe phase change to enhance the latent heat exchange ability.

The present invention has been described with the above embodiments thereof and it is understood that many changes and modifications in such as the form or layout pattern or practicing step of the above embodiments can be carried out without departing from the scope and the spirit of the invention that is intended to be limited only by the appended claims.

What is claimed is:

1. A vapor chamber structure comprising:
an aluminum upper plate having a first side and a second side; and
an aluminum lower plate having a third side and a fourth side, the aluminum upper plate and the aluminum lower plates being correspondingly mated with each other to define an airtight chamber, a working fluid being filled in the airtight chamber, multiple micron-sized recesses being directly formed on a surface of the third side, the micron-sized recesses being upward raised and/or downward recessed from the surface of the third side so as to enhance the boiling efficiency of the working fluid in the airtight chamber and promote liquid-vapor circulation performance of the entire vapor chamber, the aluminum upper plate and the aluminum lower plate being made of aluminum material so that the vapor chamber is lightweight and has better structural strength and is applicable to a low-temperature environment to prevent the working fluid in the airtight chamber from freezing.

2. The vapor chamber structure as claimed in claim 1, wherein the micron-sized recesses have a geometrical configuration selected from a group consisting of rectangular shape, rhombic shape, square shape, circular shape, trapezoidal shape and triangular shape.

3. The vapor chamber structure as claimed in claim 1, further comprising multiple support bodies, the support bodies upward protruding from the third side to connect with the second side of the aluminum upper plate, the support bodies and the micron-sized recesses being selectively connected with each other or staggered from each other.

4. The vapor chamber structure as claimed in claim 1, wherein the micron-sized recesses are formed on the third side by means of traditional processing or nontraditional processing, the traditional processing being selected from the group consisting of lathe, miller, planer, grinding machine and stamping press, the nontraditional processing being selected from the group consisting of laser processing, discharging processing, etching processing and 3D printing.

5. The vapor chamber structure as claimed in claim 1, wherein a sintered powder layer or a woven mesh layer is further disposed on the micron-sized recesses.

6. The vapor chamber structure as claimed in claim 1, wherein the micron-sized recesses have a width ranging from 200 μm to 300 μm and a depth ranging from 30 μm to 50 μm.

7. The vapor chamber structure as claimed in claim 1, wherein multiple ribs are raised from the third side, the ribs extending in a transverse direction and a longitudinal direction of the third side to intersect each other and define the micron-sized recesses.

8. The vapor chamber structure as claimed in claim 1, wherein multiple ribs are directly raised from the third side in an annular form to define multiple small closed sections as the micron-sized recesses.

9. The vapor chamber structure as claimed in claim 1, wherein the third side is directly formed with multiple recessed pits as the micron-sized recesses.

10. The vapor chamber structure as claimed in claim 1, wherein the third side of the aluminum lower plate has an evaporation section, a section of the fourth side corresponding to the evaporation section being in contact with at least one heat source.
